(19) United States
(12) Patent Application Publication
(10) Pub. No.: US 2015/0287681 A1
(43) Pub. Date: Oct. 8, 2015

(54) SEMICONDUCTOR PACKAGE AND METHOD FOR MANUFACTURING SAME

(71) Applicant: NEPES CO., LTD., Eumseong-gun, Chungcheongbuk-do (KR)

(72) Inventors: Say Hean Soh, Singapore (SG); Yuen Zien Siew, Kuala Lumpur (MY); Chuan Wei Wong, Singapore (SG); Siew Boon Soh, Singapore (SG); Haoyang Chen, Jiangsu (CN)

(21) Appl. No.: 14/389,763

(22) PCT Filed: Apr. 6, 2012
(86) PCT No.: PCT/KR2012/002625

§ 371 Date: May 14, 2015

(30) Foreign Application Priority Data
Mar. 30, 2012 (KR) 10-2012-0033166

(51) Int. Cl. H01L 23/538; H01L 21/683; H01L 25/065; H01L 21/3213; H01L 25/00; H01L 21/3105; H01L 21/321; H01L 21/02; H01L 21/56; H01L 21/768

(52) U.S. Cl. CPC H01L 23/5389; H01L 21/568; H01L 21/6835; H01L 23/5384; H01L 23/5386; H01L 25/0657; H01L 21/768; H01L 25/50; H01L 21/31053; H01L 21/32115; H01L 21/02068; H01L 21/3213; H01L 2221/68359; H01L 2221/68368

(57) ABSTRACT

Provided is a method of manufacturing a semiconductor package including a through wiring having precision and a low process defect. The method of manufacturing the semiconductor package includes preparing a conductive member; forming a plane part and projection parts projected from the plane part by removing portions of the conductive member; arranging the conductive member and a semiconductor chip, and forming a sealing member sealing the semiconductor chip and the conductive member; forming through wirings by exposing the projection parts of the conductive member from the sealing member; forming a re-wiring pattern layer which electrically connects the through wirings and the semiconductor chip; and forming external connection members which are electrically connected to the re-wiring pattern layer.

### TECHNICAL FIELD

The following description relates to a semiconductor package, and more particularly, to a semiconductor package including a through wiring, and a method of manufacturing the same.

### BACKGROUND ART

Recently, a chip size is decreasing according to miniaturization of process technology and diversification of a function of a semiconductor device, a pitch between electrode pads is decreasing as the number of input and output terminals is increased, and system-level package technology of integrating a plurality of devices into one package has emerged as convergence of various functions is accelerated. Further, the system-level package technology is introducing a three-dimensional stack technology capable of maintaining a short signal distance in order to minimize noise between operations and improve a signal speed. Meanwhile, in order to increase productivity and reduce product costs together with improvement needs of the technology, a semiconductor package constructed by including a plurality of semiconductor chips is being introduced.

Generally, in a conventional art, when stacking a plurality of semiconductor chips in a package, after forming a fan-out package of a lower semiconductor chip in order to interconnect an upper semiconductor chip and the lower semiconductor chip, a through hole is formed using a laser drill, etc. in a package mold, and a through wiring is formed by filling the through hole with a conductive material. There are limitations that it is difficult to form the through hole formed in the package mold precisely, and it is difficult to fill the through hole with the conductive material densely.

### DISCLOSURE

### Technical Problem

The present invention is directed to providing a method of manufacturing a semiconductor package including a through wiring having precision and a low process defect.

### Technical Solution

One aspect of the present invention provides a method of manufacturing a semiconductor package including a through wiring having precision and a low process defect. The method of manufacturing the semiconductor package includes preparing a conductive member; forming a plane part and projection parts projected from the plane part by removing portions of the conductive member; arranging the conductive member and a semiconductor chip, and forming a sealing member sealing the conductive member and the semiconductor chip; forming through wirings by exposing the projection parts of the conductive member from the sealing member; forming a re-wiring pattern layer which electrically connects the through wirings and the semiconductor chip; and forming external connection members which are electrically connected to the re-wiring pattern layer.

Another aspect of the present invention provides a semiconductor package, including: through wirings formed using projection parts formed by removing portions of a conductive member; a semiconductor chip which is surrounded by the through wirings, and is electrically connected to the through wirings; a re-wiring pattern layer which is located on the semiconductor chip, and electrically connects the through wirings and the semiconductor chip; and external connection members which are electrically connected to the re-wiring pattern layer.

Still another aspect of the present invention provides a package on package, including: a lower semiconductor package, including; lower through wirings formed using projection parts formed by removing portions of a first conductive member, a lower semiconductor chip which is surrounded by the lower through wirings and is electrically connected to the lower through wirings, a lower re-wiring pattern layer which is located on the lower semiconductor chip and electrically connects the lower through wirings and the lower semiconductor chip, and lower external connection members which are electrically connected to the lower re-wiring pattern layer, and an upper semiconductor package, including; upper through wirings formed using projection parts formed by removing portions of a second conductive member, an upper semiconductor chip which is surrounded by the upper through wirings and is electrically connected to the upper through wirings, an upper re-wiring pattern layer which is located on the upper semiconductor chip and electrically connects the upper through wirings and the upper semiconductor chip, and upper external connection members which are electrically connected to the upper re-wiring pattern layer, wherein the upper semiconductor package is located at an upper side of the lower semiconductor package, and the lower external connection members of the lower semiconductor package are electrically connected to the upper through wirings of the upper semiconductor package.

### Advantageous Effects

Unlike a conventional art of forming a through wiring by filling a through hole, the semiconductor package according to the spirit of the present invention can provide the through wiring having precision and a low process defect by previously forming a projection part from a conductive member and forming the through wiring using the projection part.

Further, since a process of forming the through hole in a sealing member and a process of filling the through hole with a conductive material are not required to form the through wiring, a manufacturing process can be simplified, yield can be increased, and process costs can be reduced.

### DESCRIPTION OF DRAWINGS

FIG. 1 is a plan view illustrating a semiconductor package according to one embodiment of the present invention;

FIG. 2 is a cross-sectional view taken along line A-A of the semiconductor package of FIG. 1 according to one embodiment of the present invention;

FIGS. 3 to 15 are cross-sectional views for describing a method of manufacturing the semiconductor package of FIG. 1 according to one embodiment of the present invention;

FIG. 16 is a cross-sectional view illustrating a package on package in which a plurality of semiconductor packages shown in FIG. 1 are stacked;

FIG. 17 is a cross-sectional view illustrating a semiconductor package according to another embodiment of the present invention;

FIG. 18 is a cross-sectional view illustrating a semiconductor package according to still another embodiment of the present invention;

FIG. 19 is a plan view illustrating a semiconductor package according to another embodiment of the present invention;

FIG. 20 is a cross-sectional view taken along line B-B of the semiconductor package of FIG. 19 according to another embodiment of the present invention; and

FIG. 21 is a cross-sectional view taken along line C-C of the semiconductor package of FIG. 19 according to another embodiment of the present invention.

### MODES OF THE INVENTION

Hereinafter, preferred embodiments of the present invention will be described with reference to accompanying drawings. Embodiments of the present invention are provided to describe more fully the spirit of the present invention to those skilled in the art, but the spirit of the present invention is not limited thereto. Rather, the embodiments are provided to describe more faithfully and fully disclosure of the present invention, and to describe more completely the spirit of the present invention to those skilled in the art. As used herein, the term “and/or” includes any and all combinations of one or more of the associated listed items. The same numeral may always mean the same component. Further, various components and regions are schematically illustrated in the drawings. Accordingly, the spirit of the present invention is not limited by a relative size or interval shown in the accompanying drawings.

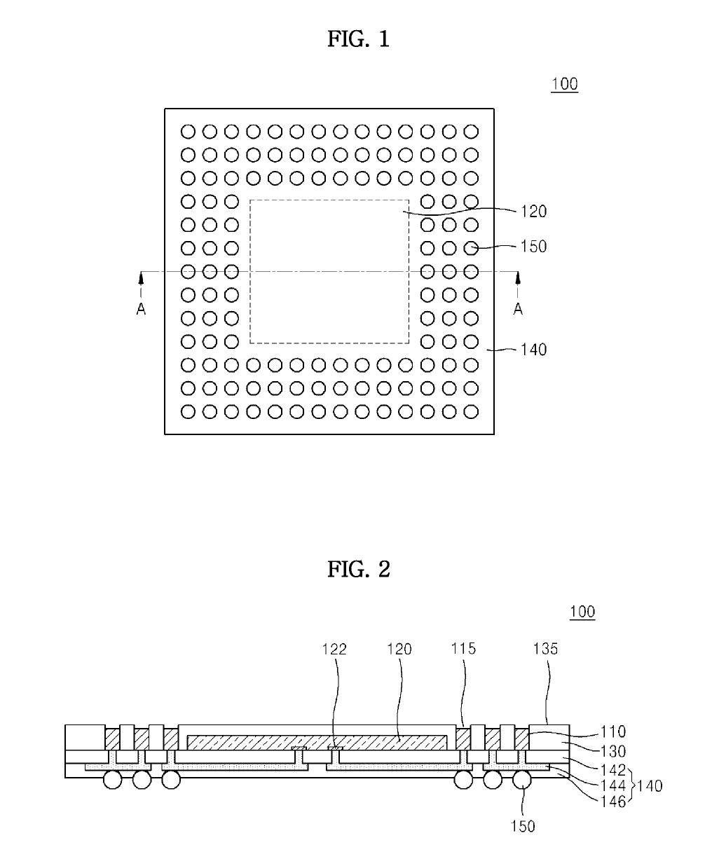

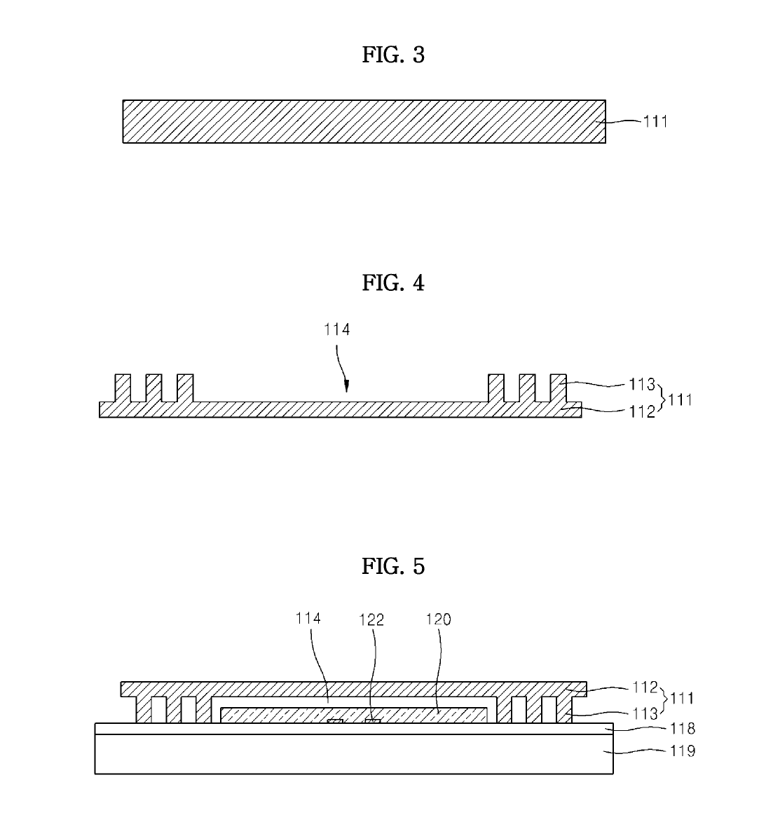

FIG. 1 is a plan view illustrating a semiconductor package 100 according to one embodiment of the present invention. FIG. 2 is a cross-sectional view taken along line A-A of the semiconductor package 100 of FIG. 1 according to one embodiment of the present invention.

Referring to FIGS. 1 and 2, the semiconductor package 100 may include a through wiring 110, a semiconductor chip 120, a sealing member 130, a re-wiring pattern layer 140, and an external connection member 150.

The semiconductor chip 120 may be located in the center of the semiconductor package 100, and the through wiring 110 may be located outside the semiconductor chip 120. The semiconductor chip 120 may be a memory chip or a logic chip. For example, the memory chip may include a dynamic random access memory (DRAM), a static random access memory (SRAM), a flash, a phase change RAM (PRAM), a resistance memory (ReRAM), a ferroelectric RAM (FeRAM), or a magnetic random access memory (MRAM). The logic chip may be a controller controlling memory chips.

The sealing member 130 may seal the semiconductor chip 120. A semiconductor chip pad 122 may be exposed from the sealing member 130. The sealing member 130 may include an insulating material, for example, an epoxy mold compound (EMC).

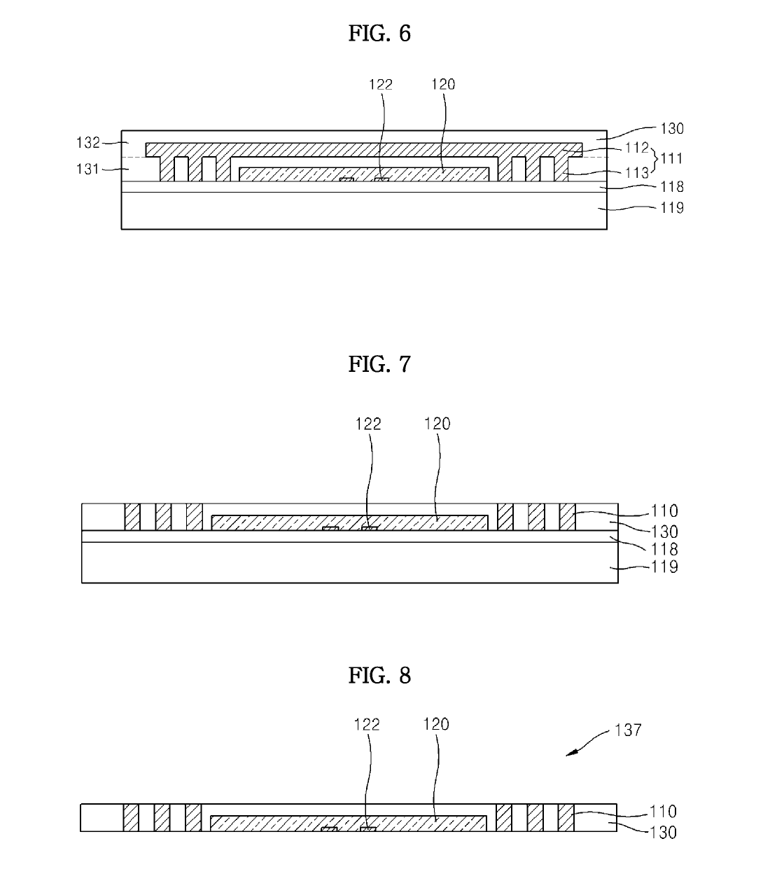

The through wiring 110 may be located to penetrate the sealing member 130. The through wiring 110 may be electrically connected to the semiconductor chip 120 by the re-wiring pattern layer 140. That is, the through wiring 110 may be electrically connected to the semiconductor chip pad 122 of the semiconductor chip 120 by a re-wiring pattern 144. The through wiring 110 may be formed using a projection part (see 113 of FIG. 4) formed from a conductive member (see 111 of FIG. 4) which will be described hereinafter with reference to FIGS. 3 to 15. A surface 115 of the through wiring 110 exposed from the sealing member 130 may be recessed more than a surface 135 of the sealing member 130.

In this embodiment, since the semiconductor chip 120 is sealed by the sealing member 130 but the through wiring 110 is exposed from the sealing member 130, the semiconductor chip 120 may have a smaller height than the through wiring 110.

A first insulating layer 142, the re-wiring pattern 144, and a second insulating layer 146 may constitute the re-wiring pattern layer 140. The re-wiring pattern 144 may be surrounded by the first insulating layer 142 and the second insulating layer 146. The re-wiring pattern 144 may include a conductive material, for example, a metal such as copper, copper alloys, aluminum, or aluminum alloys. The re-wiring pattern 144 may rewire the semiconductor chip 120. Accordingly, the re-wiring pattern 144 may miniaturize input and output terminals of the semiconductor chip 120, and also increase the number of input and output terminals. Further, the semiconductor package 100 may have a fan-out structure by the re-wiring pattern 144.

Further, the re-wiring pattern layer 140 may have a previously manufactured structure, and an example that the structure is bonded to the semiconductor chip 120 and the sealing member 130 by a pressing process, a bonding process, a reflow process, etc. may be included in the spirit of the present invention.

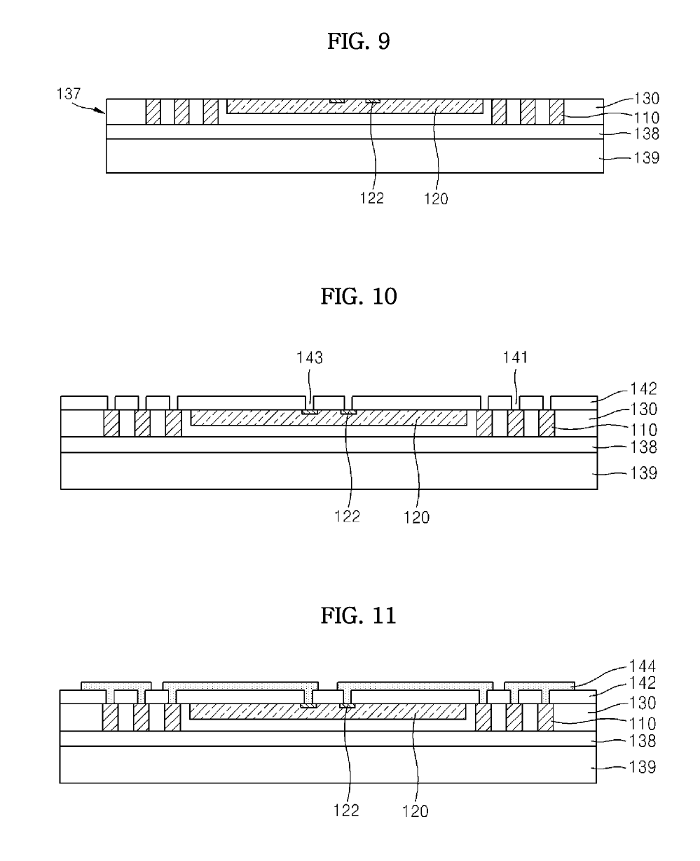

The external connection member 150 may be electrically connected to the re-wiring pattern 144, and thus be electrically connected to the semiconductor chip 120 and/or the through wiring 110. The external connection member 150 may electrically connect the semiconductor chip 120 and an external device. The external connection member 150 may be in the same vertical location as the through wiring 110. Accordingly, with reference to FIG. 16 which will be described hereinafter, the external connection member 150 of one semiconductor package may be electrically connected to the through wiring of another semiconductor package. The external connection member 150 may be located outside of the semiconductor chip 120. However, this is an example, and the spirit of the present invention is not limited thereto. An example in which the external connection member 150 is located to overlap the semiconductor chip 120 may be included in the spirit of the present invention. The external connection member 150 may be a solder ball.

FIGS. 3 to 15 are cross-sectional views for describing a method of manufacturing the semiconductor package 100 of FIG. 1 according to one embodiment of the present invention.

Referring to FIG. 3, a conductive member 111 may be prepared. The conductive member 111 may have a plate shape. The conductive member 111 may have a conductive material, for example, a metal. For example, the conductive member 111 may include copper, copper alloys, aluminum, or aluminum alloys.

Referring to FIG. 4, a plane part 112 and a projection part 113 projected from the plane part 112 may be formed by removing a portion of the conductive member 111. The process may be referred to as a half etching process, but the spirit of the present invention is not limited to an example that the projection part 113 has the same height as the plane part 112. The projection part 113 may have the same height as or a slightly greater height than the through wiring (see 110 of FIG. 7) formed in a subsequent process. The plane part 112 may have various thicknesses, and have desirably a smaller thickness for a subsequent removing process, but have a predetermined thickness to prevent warpage of the conductive member 111. A process of forming the projection part 113 may be performed by removing a portion of the conductive member 111 using photolithography and etching processes. Alternatively, the projection part 113 may be formed by pressing the conductive member 111 to a mold having a predetermined shape using a press apparatus. A recess region 114 formed by the projection part 113 may be located in the center of the conductive member 111. The recess region 114 may have a greater dimension than the semiconductor chip (see 120 of FIG. 4) to accommodate the semiconductor chip (see 120 of FIG. 4). After forming the projection part 113, a cleansing process for removing unwanted residues may be further performed.

Referring to FIG. 5, the semiconductor chip 120 may be bonded on a first carrier substrate 119. For example, the semiconductor chip 120 may be bonded on the first carrier substrate 119 using a first adhesive member 118. The semiconductor chip pad 122 of the semiconductor chip 120 may be opposite to the first carrier substrate 119, and be bonded to the first adhesive member 118. The first carrier substrate 119 may include silicon, glass, ceramic, plastic, or a polymer. The first adhesive member 118 may be a liquid adhesive or an adhesive tape. The semiconductor chip 120 may be a memory chip or a logic chip. The semiconductor chip 120 may include one semiconductor chip or a plurality of semiconductor chips.

Next, the conductive member 111 may be bonded on the first carrier substrate 119. At this time, the conductive member 111 may be overturned and be bonded on the first carrier substrate 119. The projection part 113 may be located to face the first carrier substrate 119, and be bonded to the first carrier substrate 119 by contacting the first adhesive member 118. The projection part 113 of the conductive member 111 may be located to surround the semiconductor chip 120. The semiconductor chip 120 may be located in the recess region 114 of the conductive member 111. The number of the projection parts 113 which are located on both sides of the semiconductor chip 120 may be the same. However, this is an example, and the spirit of the present invention is not limited thereto. For example, the projection part 113 may be located on only one side of the semiconductor chip 120, or the number of the projection parts 113 which are located on the both sides of the semiconductor chip 120 may be different. Further, an example in which three projection parts 113 are located on the both sides of the semiconductor chip 120 is illustrated, but this is an example, and the spirit of the present invention is not limited thereto. That is, the number of the projection parts 113 which are located on the both sides of the semiconductor chip 120 may be variably changed.

Referring to FIG. 6, the sealing member 130 sealing the semiconductor chip 120 and the conductive member 111 may be formed. Further, the sealing member 130 may fill a space between projection parts 113 of the conductive member 111 and a space between the semiconductor chip 120 and the conductive member 111. Moreover, the sealing member 130 may be formed to cover the conductive member 111. The sealing member 130 may include an insulating material, for example, an EMC. The process of forming the sealing member 130 may be performed by one singular operation, or a plurality of operations.

For example, the process of forming the sealing member 130 by the plurality of operations is as follows. A first sealing member 131 filling a space between the projection parts 113 of the conductive member 111 may be formed. Next, the sealing member 130 may be formed by forming a second sealing member 132 covering the conductive member 111. The first sealing member 131 may fill a space between the semiconductor chip 120 and the conductive member 111. An example in which the first sealing member 131 and the second sealing member 132 are divided by a dotted line is illustrated in FIG. 6,

Referring to FIG. 7, the projection part 113 of the conductive member 111 may be exposed from the sealing member 130 by removing a portion of the sealing member 130 and the plane part 112 of the conductive member 111. The exposed projection part 113 of the conductive member 111 may form the through wiring 110. The through wiring 110 may be a through silicon via (TSV) or a through substrate via (TSV). The through wiring 110 may include copper, copper alloys, aluminum, or aluminum alloys. The removing process may be performed using a polishing process, an etch-back process, or a chemical mechanical planarization (CMP) process. After the removing process is performed, the semiconductor chip 120 may be sealed by the sealing member 130. In this case, the through wiring 110 may have a greater height than the semiconductor chip 120. Alternatively, an example in which an upper surface of the semiconductor chip 120 is exposed from the sealing member 130 may be included in the spirit of the present invention. In this case, the through wiring 110 may have the same height as the semiconductor chip 120. After forming the through wiring 110, a cleansing process may be further performed in order to remove unwanted residues.

Referring to FIG. 8, the first carrier substrate 119 and the first adhesive member 118 may be removed. Accordingly, a structure 137 including the through wiring 110, the semiconductor chip 120, and the sealing member 130 may be formed. Further, the semiconductor chip pad 122 of the semiconductor chip 120 may be exposed from the sealing member 130. Moreover, an upper side and a lower side of the through wiring 110 may be exposed from the sealing member 130.

Referring to FIG. 9, the structure 137 constituted of the through wiring 110, the semiconductor chip 120, and the sealing member 130 may be bonded on a second carrier substrate 139 so that the semiconductor chip pad 122 of the semiconductor chip 120 is exposed. That is, the structure 137 may be bonded on the second carrier substrate 139 so that the second carrier substrate 139 is be located to face the semiconductor chip pad 122. For example, the structure 137 may be bonded on the second carrier substrate 139 using a second adhesive member 138. The second carrier substrate 139 may include silicon, glass, ceramic, plastic, or a polymer. The first carrier substrate 119 and the second carrier substrate 139 may have the same material or different materials. The second adhesive member 138 may be a liquid adhesive or an adhesive tape. The first adhesive member 118 and the second adhesive member 138 may have the same material or different materials.

Referring to FIGS. 10 to 12, the re-wiring pattern layer 140 which electrically connects the through wiring 110 and the semiconductor chip 120 may be formed.

Referring to FIG. 10, the first insulating layer 142 may be formed on the structure 137. Specifically, the first insulating layer 142 may be formed on the through wiring 110 and the semiconductor chip 120. Next, a first opening 141 exposing the through wiring 110 and a second opening 143 exposing the semiconductor chip pad 122 of the semiconductor chip 120 may be formed by removing a portion of the first insulating layer 142. The first insulating layer 142 may include an insulating material, for example, an oxide, a nitride, or an EMC, etc.

Referring to FIG. 11, the re-wiring pattern 144 which electrically connects the through wiring 110 and the semiconductor chip pad 122 of the semiconductor chip 120 may be formed on the first insulating layer 142. The re-wiring pattern 144 may fill the first opening 141, and thus the re-wiring pattern 144 may be electrically connected to the through wiring 110. The re-wiring pattern 144 may also fill the second opening 143, and thus the re-wiring pattern 144 may be electrically connected to the semiconductor chip pad 122. The re-wiring pattern 144 may include a conductive material, for example, a metal such as copper, copper alloys, aluminum, or aluminum alloys. The re-wiring pattern 144 may be formed using various methods such as a deposition process, a plating process, etc. The re-wiring pattern 144 may rewire the semiconductor chip 120. The re-wiring pattern 144 may be electrically connected to the external connection member (see 150 of FIG. 13). Accordingly, the re-wiring pattern 144 may miniaturize the input and output terminals of the semiconductor chip 120, and also increase the number of the input and output terminals. Further, the semiconductor package 100 may have a fan-out structure by the re-wiring pattern 144.

Referring to FIG. 12, the second insulating layer 146 may be formed on the re-wiring pattern 144. Next, a third opening 145 exposing a portion of the re-wiring pattern 144 may be formed by removing a portion of the second insulating layer 146. The second insulating layer 146 may include an insulating material, for example, an oxide, a nitride, or an EMC, etc. The first insulating layer 142 and the second insulating layer 146 may include the same material or different materials. The first insulating layer 142, the re-wiring pattern 144, and the second insulating layer 146 may constitute the re-wiring pattern layer 140.

Further, the re-wiring pattern layer 140 may be constituted by a previously manufactured structure, and an example that the structure is bonded to the semiconductor chip 120 and the sealing member 130 by a pressing process, a bonding process, a reflow process, etc. may be included in the spirit of the present invention.

Referring to FIG. 13, the external connection member 150 which is electrically connected to the re-wiring pattern 144 may be formed. The external connection member 150 may be bonded to the exposed re-wiring pattern 144. The external connection member 150 may include a conductive material, for example, a metal. The external connection member 150 may be a solder ball.

Referring to FIG. 14, the second carrier substrate 139 and the second adhesive member 138 may be removed. Accordingly, the through wiring 110 may be exposed from the sealing member 130. In this process, a manufacturing process of the semiconductor package may be completed.

Referring to FIG. 15, the through wiring 110 having the surface 115 recessed more than the surface 135 of the sealing member 130 may be formed by removing a portion of the exposed through wiring 110. The process of removing the portion of the through wiring 110 may be performed using a wet etching process. The surface 115 of the through wiring 110 may be cleansed by the wet etching process. Accordingly, the semiconductor package 100 of FIG. 1 may be manufactured.

FIG. 16 is a cross-sectional view illustrating a package on package (PoP) 1000 in which a plurality of semiconductor packages 100 shown in FIG. 1 are stacked. Duplicate descriptions between the PoP 1000 according to an embodiment of the present invention and the semiconductor package 100 described above will be omitted.

Referring to FIG. 16, the PoP 1000 may include semiconductor packages 100A, 100B, and 100C which are vertically stacked. Specifically, the semiconductor package 100B may be located on the semiconductor package 100A, and the semiconductor package 100C may be located on the semiconductor package 100B. Further, an example of forming a PoP in which two or more semiconductor packages are stacked may be included in the spirit of the present invention.

An external connection member 150A of the semiconductor package 100A may be electrically connected to a through wiring 110B of the semiconductor package 100B. For this connection, as described with reference to FIG. 15, the through wiring 110B may have a recessed surface (see 115 of FIG. 15), and the external connection member 150A may be aligned and/or fixed by a sealing member 130B.

An external connection member 150B of the semiconductor package 100B may be electrically connected to a through wiring 110C of the semiconductor package 100C. For this connection, the through wiring 110C may have a recessed surface (see 115 of FIG. 15), and the external connection member 150B may be aligned and/or fixed by a sealing member 130C.

An external connection member 150C of the semiconductor package 100C may be electrically connected to an external device such as an external substrate (not shown).

Hereinafter, an electrical connection relation of the semiconductor packages 100A, 100B, and 100C will be described.

A semiconductor chip 120A of the semiconductor package 100A may be electrically connected to the external device through a re-wiring pattern 144A and a through wiring 110A. Further, the semiconductor chip 120A of the semiconductor package 100A may be electrically connected to the external device through the re-wiring pattern 144A, the external connection member 150A, the through wiring 110B, a re-wiring pattern 144B, the external connection member 150B, the through wiring 110C, a re-wiring pattern 144C, and the external connection member 150C.

The semiconductor chip 120A of the semiconductor package 100A may be electrically connected to a semiconductor chip 120B of the semiconductor package 100B through the re-wiring pattern 144A, the external connection member 150A, the through wiring 110B, and the re-wiring pattern 144B.

The semiconductor chip 120A of the semiconductor package 100A may be electrically connected to a semiconductor chip 120C of the semiconductor package 100C through the re-wiring pattern 144A, the external connection member 150A, the through wiring 110B, the re-wiring pattern 144B, the external connection member 150B, the through wiring 110C, and the re-wiring pattern 144C.

The semiconductor chip 120B of the semiconductor package 100B may be electrically connected to the external device through the re-wiring pattern 144B, the through wiring 110B, the external connection member 150A, the re-wiring pattern 144A, and the through wiring 110A. Further, the semiconductor chip 120B of the semiconductor package 100B may be electrically connected to the external device through the re-wiring pattern 144B, the external connection member 150B, the through wiring 110C, the re-wiring pattern 144C, and the external connection member 150C.

The semiconductor chip 120B of the semiconductor package 100B may be electrically connected to the semiconductor chip 120C of the semiconductor package 100C through the re-wiring pattern 144B, the external connection member 150B, the through wiring 110C, and the re-wiring pattern 144C.

The semiconductor chip 120C of the semiconductor package 100C may be electrically connected to the external device through the re-wiring pattern 144C, the through wiring 110C, the external connection member 150B, the re-wiring pattern 144B, the through wiring 1108, the external connection member 150A, the re-wiring pattern 144A, and the through wiring 110A. Further, the semiconductor chip 120C of the semiconductor package 100C may be electrically connected to the external device through the re-wiring pattern 144C and the external connection member 150C.

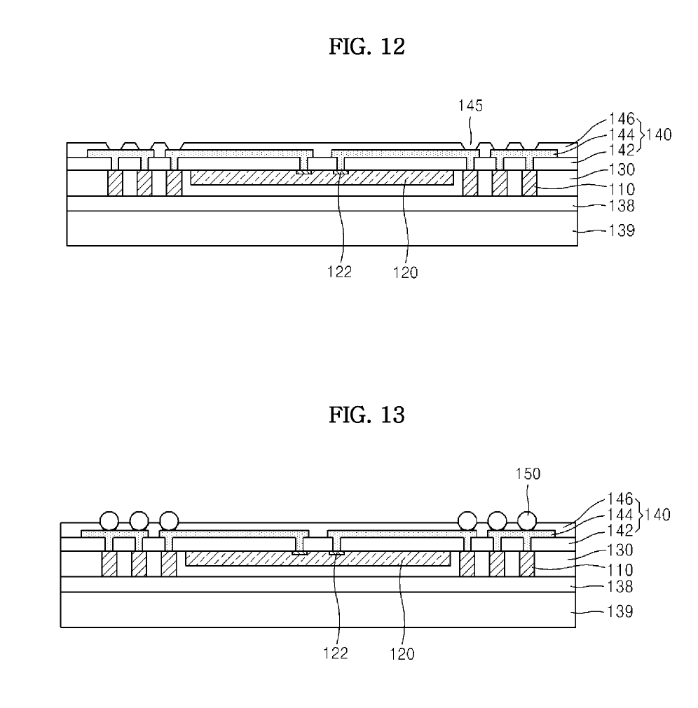

FIG. 17 is a cross-sectional view illustrating a semiconductor package 200 according to another embodiment of the present invention. The semiconductor package 200 according to another embodiment of the present invention may be constituted by modifying some configuration of the semiconductor package described above, and duplicate descriptions will be omitted.

Referring to FIG. 17, the semiconductor package 200 may include a through wiring 110, a semiconductor chip 120, a sealing member 230, a re-wiring pattern layer 140, and an external connection member 150. A side of the semiconductor chip 120 may be surrounded by the sealing member 230, but a surface of the semiconductor chip 120 may be exposed from the sealing member 230. As described above with reference to FIG. 7, the structure may be implemented by performing the process so that the surface of the semiconductor chip 120 is exposed when removing the portion of the sealing member and the plane part of the conductive member. In this embodiment, the semiconductor chip 120 may have the same height as the through wiring 110. Further, when the through wiring 110 has a surface recessed from the sealing member 230, the semiconductor chip 120 may have a greater height than the through wiring 110.

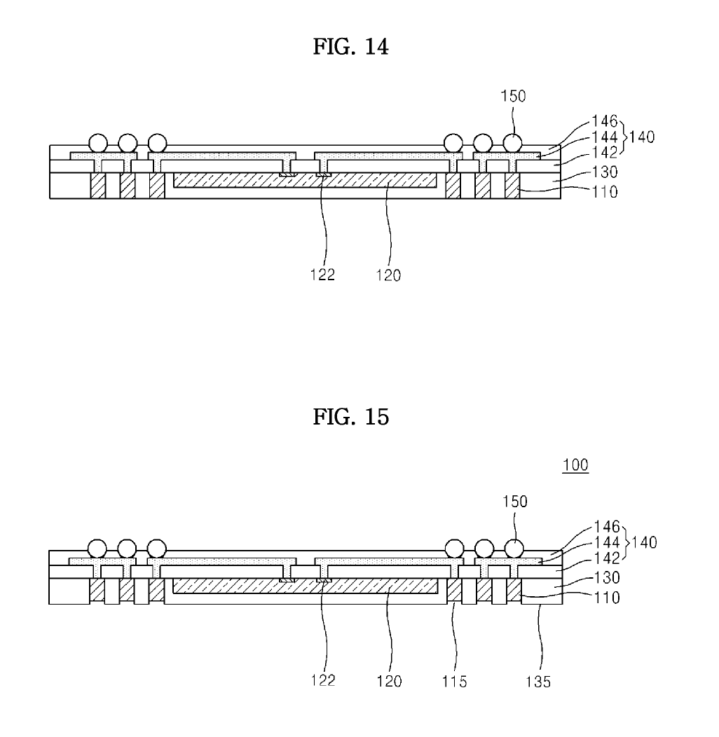

FIG. 18 is a cross-sectional view illustrating a semiconductor package 300 according to still another embodiment of the present invention. The semiconductor package 300 according to still another embodiment of the present invention may be constituted by modifying some configuration of the semiconductor package described above, and duplicate description will be omitted.

Referring to FIG. 18, the semiconductor package 300 may include a through wiring 110, a first semiconductor chip 320a, a second semiconductor chip 320b, a sealing member 130, a re-wiring pattern layer 140, and an external connection member 150. The first semiconductor chip 320a and the second semiconductor chip 320b may be electrically connected to the re-wiring pattern layer 140 like the semiconductor chip 120 of FIG. 1. The first semiconductor chip 320a and the second semiconductor chip 320b may have the same size or different sizes. The first semiconductor chip 320a and the second semiconductor chip 320b may be memory chips or logic chips. Further, the first semiconductor chip 320a may be a product of the same kind having the same function as or a product of a different kind having a different function from the second semiconductor chip 320b. For example, the first semiconductor chip 320a may be the logic chip, and the second semiconductor chip 320b may be the memory chip, or vice versa. The semiconductor package 300 may be a system on chip (SOC) or a system in package (SIP).

An example in which the first semiconductor chip 320a and the second semiconductor chip 320b are arranged in a horizontal direction is illustrated in FIG. 18, but an example in which the first semiconductor chip 320a and the second semiconductor chip 320b are stacked in a vertical direction may be included in the spirit of the present invention. Further, an example of combining the technical features of the semiconductor package 200 of FIG. 17 and the semiconductor package 300 of FIG. 18 may be included in the spirit of the present invention.

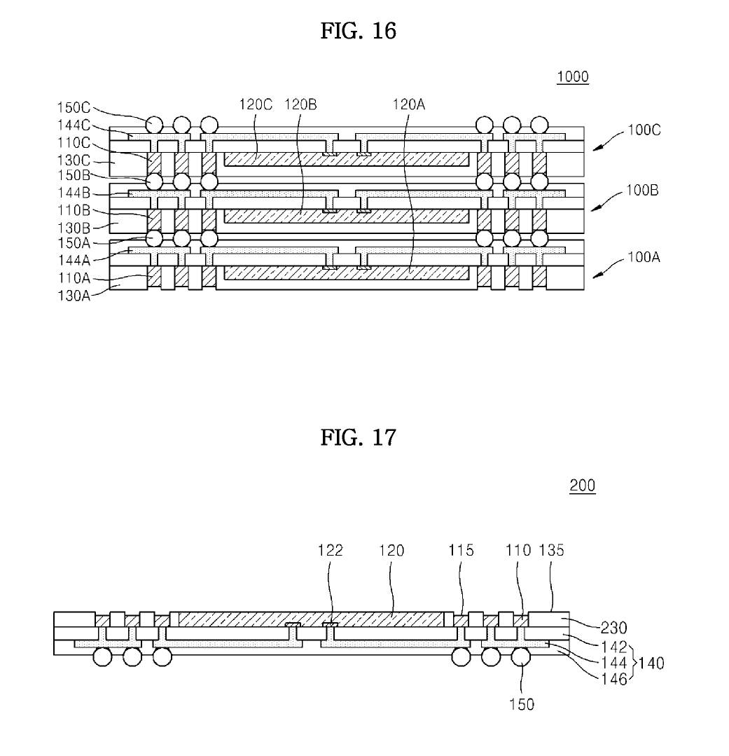

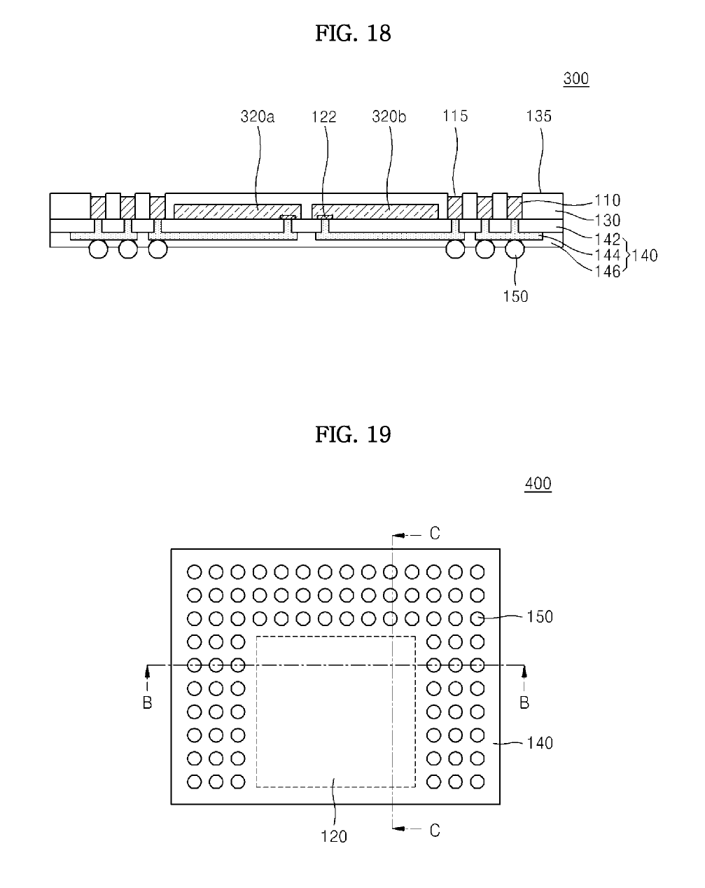

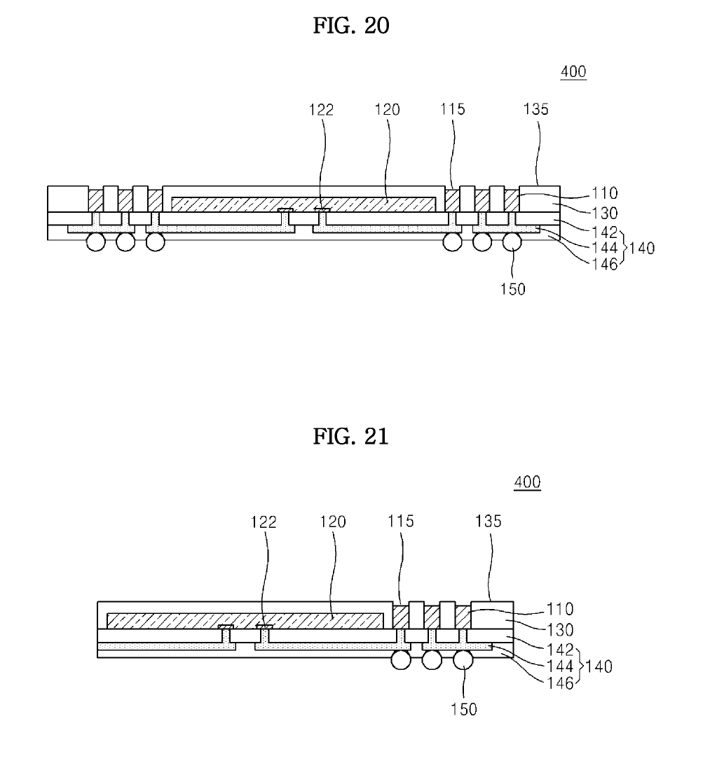

FIG. 19 is a plan view illustrating a semiconductor package 400 according to another embodiment of the present invention. FIG. 20 is a cross-sectional view taken along line B-B of the semiconductor package 400 of FIG. 19 according to another embodiment of the present invention. FIG. 21 is a cross-sectional view taken along line C-C of the semiconductor package 400 of FIG. 19 according to another embodiment of the present invention.

The semiconductor package 400 according to yet another embodiment of the present invention may be constituted by modifying some configuration of the semiconductor package described above, and duplicate descriptions will be omitted.

Referring to FIGS. 19 to 21, the semiconductor package 400 may include a through wiring 110, a semiconductor chip 120, a sealing member 130, a re-wiring pattern layer 140, and an external connection member 150.

Unlike the semiconductor package 100 described with reference to FIGS. 1 and 2, the semiconductor chip 120 of the semiconductor package 400 may be located in one side of the semiconductor package 400. That is, the external connection member 150 may be located in three sides of the semiconductor chip 120, but may not be located in one side of the semiconductor chip 120. Accordingly, the through wiring 110 may not be located in the one side of the semiconductor chip 120 in which the external connection member 150 is not located. This is an example with respect to a location relation between the semiconductor chip 120 and the external connection member 150, and an example in which the location relation is variably changed may be also included in the spirit of the present invention. Further, an example of combining the technical features of the semiconductor package 200 of FIG. 17 and/or the semiconductor package 300 of FIG. 18 and the semiconductor package 400 of FIG. 20 may be included in the spirit of the present invention.

While the invention has been shown and described with reference to certain exemplary embodiments thereof, it will be understood by those skilled in the art that various changes in form and details may be made therein without departing from the spirit and scope of the invention as defined by the appended claims.

1. A method of manufacturing a semiconductor package, comprising:
preparing a conductive member;
forming a plane part and projection parts projected from the plane part by removing portions of the conductive member;
arranging the conductive member and a semiconductor chip, and forming a sealing member sealing the semiconductor chip and the conductive member;
forming through wirings by exposing the projection parts of the conductive member from the sealing member;
forming a re-wiring pattern layer which electrically connects the through wirings and the semiconductor chip; and
forming external connection members which are electrically connected to the re-wiring pattern layer.

2. The method of manufacturing the semiconductor package according to claim 1, wherein the arranging of the conductive member and the semiconductor chip further comprises:
bonding the conductive member and the semiconductor chip on a first carrier substrate.

3. The method of manufacturing the semiconductor package according to claim 2, between the forming of the through wirings and the forming of the forming of the re-wiring pattern layer, further comprising:
removing the first carrier substrate; and
bonding the through wirings and the semiconductor chip on a second carrier substrate so that a semiconductor chip pad of the semiconductor chip is exposed.

4. The method of manufacturing the semiconductor package according to claim 3, after performing the forming of the external connection members which are electrically connected to the re-wiring pattern layer, further comprising:
exposing the through wirings from the sealing member by removing the second carrier substrate; and
forming the through wirings having surfaces which are recessed more than a surface of the sealing member by removing portions of the exposed through wirings.

5. The method of manufacturing the semiconductor package according to claim 4, wherein the forming of the through wirings having the surfaces which are recessed more than the surface of the sealing member is performed using a wet etching process.

6. The method of manufacturing the semiconductor package according to claim 1, wherein after performing the forming of the projection parts, further comprising:
cleansing the conductive member in which the projection parts are formed to remove unwanted residues.

7. The method of manufacturing the semiconductor package according to claim 2, wherein the bonding of the conductive member and the semiconductor chip on the first carrier substrate, comprises:
bonding the semiconductor chip on the first carrier substrate; and
bonding the conductive member on the first carrier substrate so that the projection parts of the conductive member surround the semiconductor chip.

8. The method of manufacturing the semiconductor package according to claim 1, wherein the forming of the sealing member sealing the semiconductor chip and the conductive member, comprises:
forming a first sealing member filling a space between the projection parts of the conductive member; and
forming a second sealing member covering the conductive member.

9. The method of manufacturing the semiconductor package according to claim 1, wherein the forming of the through wirings by exposing the projection parts of the conductive member from the sealing member, comprises:
removing a portion of the sealing member and the plane part of the conductive member using a polishing process, an etch-back process, or a chemical mechanical planarization (CMP) process.

10. The method of manufacturing the semiconductor package according to claim 9, wherein the forming of the through wirings by exposing the projection parts of the conductive member from the sealing member, further comprises:
after performing the removing of the portion of the sealing member and the plane part of the conductive member using the polishing process, the etch-back process, or the chemical mechanical planarization (CMP) process, cleansing the through wirings to remove unwanted residues.

11. The method of manufacturing the semiconductor package according to claim 1, wherein the forming of the re-wiring pattern layer which electrically connects the through wirings and the semiconductor chip, comprises:
forming a first insulating layer exposing the through wirings and a semiconductor chip pad of the semiconductor chip on the through wirings and the semiconductor chip;
forming a re-wiring pattern which electrically connects the through wirings and the semiconductor chip pad on the first insulating layer; and
forming a second insulating layer exposing a portion of the re-wiring pattern on the re-wiring pattern.

12. The method of manufacturing the semiconductor package according to claim 1, wherein the forming of the projection parts comprises,
forming the projection parts by removing portions of the conductive member using photolithography and etching processes.

13. The method of manufacturing the semiconductor package according to claim 1, wherein the forming of the projection parts comprises,
forming the projection parts by pressing the conductive member.

14. A semiconductor package, comprising:
through wirings formed using projection parts formed by removing portions of a conductive member;
a semiconductor chip which is surrounded by the through wirings, and is electrically connected to the through wirings;
a re-wiring pattern layer which is located on the semiconductor chip, and electrically connects the through wirings and the semiconductor chip; and
external connection members which are electrically connected to the re-wiring pattern layer.

15. The semiconductor package according to claim 14, wherein heights of the through wirings are greater than a height of the semiconductor chip.

16. The semiconductor package according to claim 14, wherein heights of the through wirings are equal to a height of the semiconductor chip.

17. The semiconductor package according to claim 14, wherein heights of the through wirings are smaller than a height of the semiconductor chip.

18. The semiconductor package according to claim 14, wherein the semiconductor chip comprises a plurality of semiconductor chips.

19. The semiconductor package according to claim 14, wherein the through wirings are located on at least one side of the semiconductor chip.

20. A package on package, comprising:
a lower semiconductor package, comprising;
lower through wirings formed using projection parts formed by removing portions of a first conductive member,
a lower semiconductor chip which is surrounded by the lower through wirings, and is electrically connected to the lower through wirings,
a lower re-wiring pattern layer which is located on the lower semiconductor chip, and electrically connects the lower through wirings and the lower semiconductor chip, and
lower external connection members which are electrically connected to the lower re-wiring pattern layer, and
an upper semiconductor package, comprising;
upper through wirings formed using projection parts formed by removing portions of a second conductive member,
an upper semiconductor chip which is surrounded by the upper through wirings, and is electrically connected to the upper through wirings,
an upper re-wiring pattern layer which is located on the upper semiconductor chip, and electrically connects the upper through wirings and the upper semiconductor chip, and
upper external connection members which are electrically connected to the upper re-wiring pattern layer,
wherein the upper semiconductor package is located at an upper side of the lower semiconductor package, and the lower external connection members of the lower semiconductor package are electrically connected to the upper through wirings of the upper semiconductor package.
